(19) United States
(12) Patent Application Publication
(10) Pub. No.: US 2020/0335429 A1
(43) Pub. Date: Oct. 22, 2020

(54) FLEXIBLE PRINTED CIRCUIT BOARD AND METHOD OF MANUFACTURING FLEXIBLE PRINTED CIRCUIT BOARD

(71) Applicant: SUMITOMO ELECTRIC PRINTED CIRCUITS, INC., Shiga (JP)

(72) Inventors: Junichi OKAUE, Shiga (JP); Hisao OKADA, Shiga (JP)

(21) Appl. No.: 16/763,338

(22) PCT Filed: Nov. 23, 2018
(86) PCT No.: PCT/JP2018/043298

§ 371 Date: May 12, 2020

(30) Foreign Application Priority Data
Nov. 27, 2017 (JP) 2017-226635

(51) Int. Cl. H01L 23/498; H01L 21/48; H01L 23/00

(52) U.S. Cl. CPC H01L 23/4985; H01L 23/49866; H01L 23/49838; H01L 2224/80203; H01L 24/80; H01L 2224/80805; H01L 21/4846

(57) ABSTRACT

According to one aspect of the present disclosure, a flexible printed circuit board includes: an insulating base film; a first conductive pattern that is layered on the base film and that is coated with gold, nickel, or an anti-rust material; and a second conductive pattern that is layered on the base film and that is coated with tin or solder.

### TECHNICAL FIELD

The present disclosure relates to a flexible printed circuit board and a method of manufacturing a flexible printed circuit board.

The present application is based on and claims priority to Japanese Patent Application No. 2017-226635, filed on Nov. 27, 2017, the entire contents of the Japanese Patent Application are hereby incorporated herein by reference.

### BACKGROUND ART

In an electronic device with a display panel, generally, the display panel and a printed circuit board are connected by means of a COF (Chip on Film) with a mounted IC chip that drives the display panel (see Japanese Laid-open Patent Publication No. 2016-20779).

For a COF, copper foil layered on a polyimide film is wet etched to form a wiring pattern and an IC is flip-chip mounted on the wiring pattern. Among electronic devices with display panels, there is an electronic device in which the display panel and a printed circuit board having a main circuit are connected by means of a COF with a mounted IC for driving the display panel.

In a COF, a configuration may be employed in which the surface of a wiring pattern is coated with tin and an IC chip is connected to the wiring pattern by a brazing material generated by a eutectic reaction of the tin with a gold layer on the outer terminal surface of the IC chip. A connection method by such a eutectic reaction is called eutectic bonding and can be performed by thermal compression bonding at a relatively low temperature.

### PRIOR ART DOCUMENT

### [Patent Document]

[Patent Document 1] Japanese Laid-open Patent Publication No. 2016-207792

### SUMMARY OF THE INVENTION

According to one aspect of the present disclosure, a flexible printed circuit board includes: an insulating base film; a first conductive pattern that is layered on the base film and that is coated with gold, nickel, or an anti-rust material; and a second conductive pattern that is layered on the base film and that is coated with tin or solder.

According to another aspect of the present disclosure, a method of manufacturing a flexible printed circuit board includes: a step of forming a conductive pattern on an insulating base film; a step of coating a portion of the conductive pattern with gold, nickel, or an anti-rust material; and after the step of coating, a step of coating another portion of the conductive pattern with tin or solder.

### BRIEF DESCRIPTION OF THE DRAWINGS

FIG. 1 is a schematic plan view of a flexible printed circuit board according to one embodiment of the present disclosure;

FIG. 2 is a schematic cross-sectional view of the flexible printed circuit board of FIG. 1;

FIG. 3 is a schematic plan view of a tin coating layer;

FIG. 4 is a schematic cross-sectional view of the tin coating layer;

FIG. 5 is a schematic cross-sectional view of a display device using the flexible printed circuit board of FIG. 1;

FIG. 6 is a schematic plan view of a flexible printed circuit board according to an embodiment different from that of FIG. 1 of the present disclosure; and

FIG. 7 is a schematic cross-sectional view of the flexible printed circuit board of FIG. 6.

### EMBODIMENT FOR CARRYING OUT THE INVENTION

### Problem to be Solved by the Present Disclosure

In a COF for a display panel, because an IC chip for driving the display panel is mounted on a surface that is the same as the surface where terminals connected to the display panel and terminals connected to a printed circuit board are disposed, the arrangement in an electronic device is limited. Also, the COF is weak in bending in comparison to a general flexible printed circuit board, and disconnection easily occurs.

In view of above, the present disclosure has an object to provide a flexible printed circuit board and a method of manufacturing a flexible printed circuit board that enable to mount an IC chip and that can be directly connected to terminals of another device, a circuit, or the like.

### Effect of the Present Disclosure

A flexible printed circuit board according to one aspect of the present disclosure and a flexible printed circuit board that is obtained by a method of manufacturing a flexible printed circuit board according to another aspect of the present disclosure enables to mount an IC chip and can be directly connected to terminals of another device, a circuit board, or the like.

### Description of Embodiments of the Present Disclosure

According to one aspect of the present disclosure, a flexible printed circuit board includes: an insulating base film; a first conductive pattern that is layered on the base film and that is coated with gold, nickel, or an anti-rust material; and a second conductive pattern that is layered on the base film and that is coated with tin or solder.

In the flexible printed circuit board, because the first conductive pattern is coated with gold, nickel, or an anti-rust material, the conductive connectivity of the first conductive pattern to other circuits does not easily decrease. Therefore, the flexible printed circuit board can be securely connected to terminals of another device or a circuit board. Also, in the flexible printed circuit board, because the second conductive pattern is coated with tin or solder, an IC chip can be easily and securely mounted on the second conductive pattern by a eutectic reaction.

In the flexible printed circuit board, the second conductive pattern may include lands for IC chip mounting. In this way, by the second conductive pattern including lands for IC chip mounting, an IC chip can be more easily and securely mounted on the second conductive pattern by a eutectic reaction.

In the flexible printed circuit board, the first conductive pattern may include a narrow pitch connection portion where a plurality of terminals are arranged and formed with an average width of 15 μm or less and at an average interval of 15 μm or less. In this way, the first conductive pattern including the narrow pitch connection portion enables direct connection with terminals with a relatively small wire pitch.

In the flexible printed circuit board, the first conductive pattern may include a wide pitch connection portion where a plurality of terminals are arranged and formed with an average width of 20 μm or more and at an average interval of 20 μm or more. In this way, by the first conductive pattern including the wide pitch connection portion, the flexible printed circuit board can be used to connect a display panel or the like to another printed circuit board or the like.

In the flexible printed circuit board, the second conductive pattern may be coated with tin, a layer coated with tin may include, on its outer surface, one or more first areas formed by an alloy of a metal and tin forming the second conductive pattern and one or more second areas formed by unalloyed tin, and a total occupying area percentage of the one or more first areas in the outer surface of the layer coated with tin may be greater than or equal to 2% and less than or equal to 90%. In this way, by the total occupying area percentage of the one or more first areas in the outer surface of the layer coated with tin being greater than or equal to 2% and less than or equal to 90%, the amount of brazing material formed by a eutectic reaction at the time of bonding with terminals of an IC chip can be made appropriate, a short circuit between adjacent circuits of the second conductive pattern can be prevented, and the bonding with the terminals of the IC chip can be more secured.

In the flexible printed circuit board, an average thickness of the second areas may be greater than or equal to 0.05 μm and less than or equal to 0.4 μm. In this way, by the average thickness of the second areas being greater than or equal to 0.05 μm and less than or equal to 0.4 μm, the amount of brazing material formed by a eutectic reaction at the time of bonding with terminals of an IC chip can be made appropriate, a short circuit between adjacent circuits of the second conductive pattern can be prevented, and the bonding with the terminals of the IC chip can be more secured.

According to another aspect of the present disclosure, a method of manufacturing a flexible printed circuit board includes: a step of forming a conductive pattern on an insulating base film; a step of coating a portion of the conductive pattern with gold, nickel, or an anti-rust material; and after the step of coating, a step of coating another portion of the conductive pattern with tin or solder.

Because the method of manufacturing a flexible printed circuit board performs coating with tin or solder after coating with gold, nickel, or an anti-rust material, a coating layer of gold, nickel, or an anti-rust material and a coating layer of tin or solder can be appropriately formed. Therefore, according to the method of manufacturing a flexible printed circuit board, it is possible to obtain a printed circuit board that enables to mount an IC chip and that can be directly connected to terminals of another device, a circuit, or the like.

In the method of manufacturing a flexible printed circuit board, coating with the gold or nickel may be performed by electroless plating, and coating with the tin or solder may be performed by electroless plating.

In this way, by coating with the gold or nickel being performed by electroless plating, and by coating with the tin or solder being performed by electroless plating, the connectivity of the coating with gold or nickel and the coating with tin or solder can be prevented from being impaired. Also, by performing electroless plating for coating with gold or nickel and for coating with tin or solder, it is possible to obtain a flexible printed circuit board that enables to connect terminals of an IC chip more easily and reliably.

In the method of manufacturing a flexible printed circuit board, the portion of the conductive pattern that is coated with tin or solder may include lands for IC chip mounting, and the method may further include a step of eutectic bonding terminals of an IC chip to the lands for IC chip mounting. In this way, by the portion of the conductive pattern that is coated with tin or solder including the lands for IC chip mounting and by including the step of eutectic bonding the terminals of the IC chip to the lands for IC chip mounting, it is possible to obtain a flexible printed circuit board that enables to mount the IC chip more reliably by eutectic bonding.

In the method of manufacturing a flexible printed circuit board, in the step of eutectic bonding, by thermal compression bonding at a temperature of 250° C. or more and 500° C. or less and at a pressure of 2 MPaG or more and 50 MPaG or less, eutectic bonding may be performed. In this way, by performing eutectic bonding by thermal compression bonding at a temperature of 250° C. or more and 500° C. or less and at a pressure of 2 MPaG or more and 50 MPaG or less, deterioration of the flexible printed circuit board can be prevented and the bonding strength of terminals of an IC chip to lands for IC chip mounting can be further enhanced.

It should be noted that the “anti-rust material” is a concept that includes an organic material that forms a coating on the surface of the material that forms the first conductive pattern, and includes a material that is chemically bonded with the material that forms the first conductive pattern to form a passivation (including one being bonded).

### Details of Embodiments of the Present Disclosure

In the following, embodiments of flexible printed circuit boards according to the present disclosure will be described in detail with reference to the drawings.

### First Embodiment

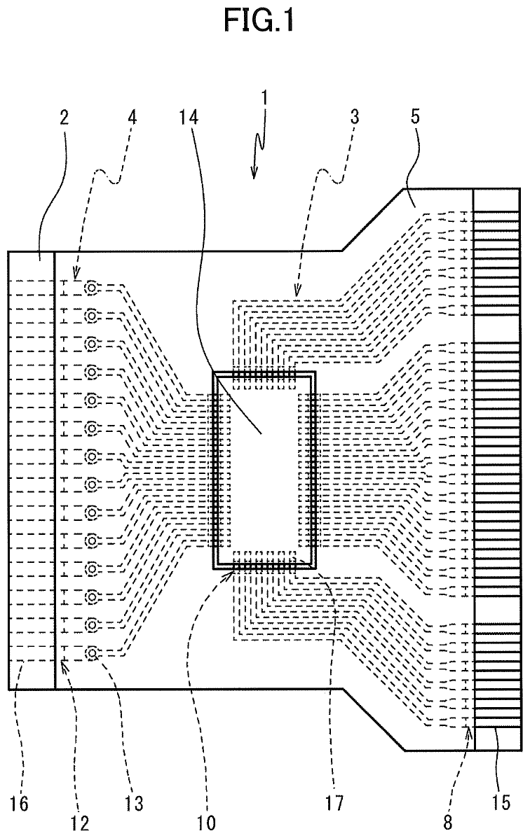

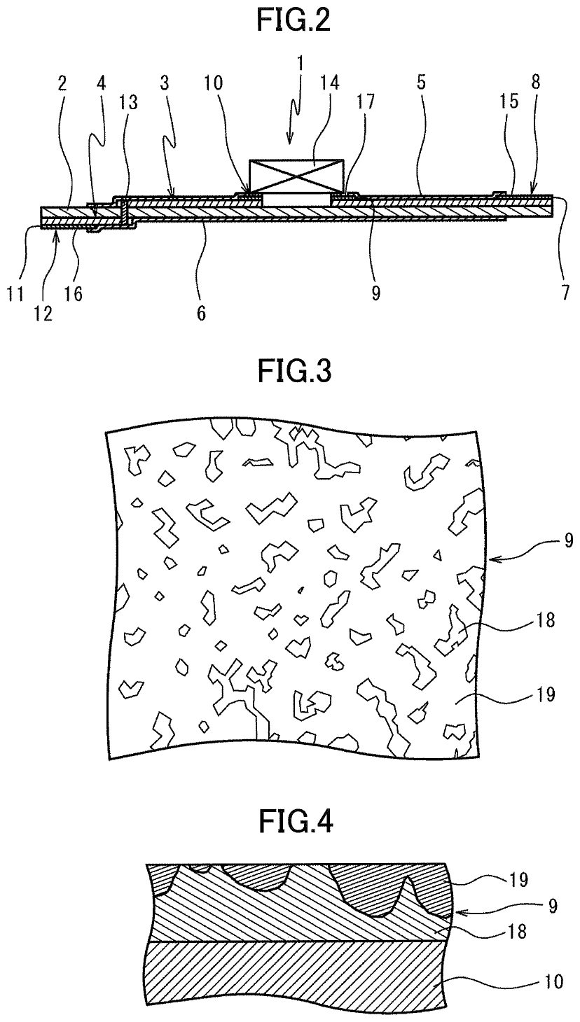

FIG. 1 and FIG. 2 illustrate a flexible printed circuit board 1 according to one embodiment of the present disclosure. The flexible printed circuit board 1 further includes an insulating base film 2, a front surface conductive pattern 3 that is layered on the front surface side of the base film 2, a back surface conductive pattern 4 that is layered on the back surface side of the base film 2, a front surface protective layer 5 that partially covers the front surface conductive pattern 3, and a back surface protective layer 6 that partially covers the back surface conductive pattern 4.

The front surface conductive pattern 3 includes a front surface first conductive pattern 8 that is coated by a gold coating layer 7 and includes a second conductive pattern 10 that is coated by a tin coating layer 9. The front surface first conductive pattern 8 and the second conductive pattern 10 are present at portions that are exposed from the front surface protective layer 5. In other words, at the front surface conductive pattern 3, the gold coating layer 7 or the tin coating layer 9 is layered at the portion that is exposed from the front surface protective layer 5. On the other hand, at the portion that is coated with the front surface protective layer 5 at the front surface conductive pattern 3, the gold coating layer 7 and the tin coating layer 9 may not be layered.

The back surface conductive pattern 4 includes a back surface first conductive pattern 12 that is coated with the gold coating layer 11, but not include a conductive pattern that is coated with tin. The back surface first conductive pattern 12 is present at a portion that is exposed from the back surface protective layer 6.

The front surface conductive pattern 3 and the back surface conductive pattern 4 are connected by through holes 13 that are formed to pass through the base film 2.

Also, an IC chip 14 is mounted on the front surface conductive pattern 3 of the flexible printed circuit board 1.

<Base Film>

The base film 2 is formed of a material having a synthetic resin as the main component and has flexibility. Examples of the main component of the base film 2 include a soft material such as polyimide, liquid crystal polyester, polyethylene terephthalate, polyethylene naphthalate, and fluororesin. Among these, polyimide excellent in insulation properties, flexibility, heat resistance, and the like is preferable. Also, the base film 2 may be porous, and may contain a filler, an additive, or the like.

The lower limit of the average thickness of the base film 2 is not particularly limited but is preferably 5 μm and is more preferably 12 μm. On the other hand, the upper limit of the average thickness of the base film 2 is preferably 2 mm, and is more preferably 1.6 mm. In a case in which the average thickness of the base film 2 is less than the lower limit, the strength of the base film 2 or the base material for a printed circuit board may be insufficient. On the contrary, in a case in which the average thickness of the base film 2 exceeds the upper limit, the flexibility of the flexible printed circuit board 1 may be insufficient.

<Conduction Pattern>

The front surface conductive pattern 3 and the back surface conductive pattern 4 can be formed by patterning a layer of a layered conductor of the base film 2.

Examples of the material of the conductor that forms the front surface conductive pattern 3 and the back surface conductive pattern 4 include metals such as copper, silver, platinum, and nickel. Among these, copper that is relatively low cost and excellent in conductivity is preferable as the material of the front surface conductive pattern 3 and the back surface conductive pattern 4.

The front surface conductive pattern 3 and the back surface conductive pattern 4 are preferably formed with a substantially constant thickness. The lower limit of the average thickness of the front surface conductive pattern 3 and the back surface conductive pattern 4 is preferably 2 μm, and is more preferably 5 pin. On the other hand, the upper limit of the average thickness of the front surface conductive pattern 3 and the back surface conductive pattern 4 is preferably 50 μm, and is more preferably 40 μm. In a case in which the average thickness of the front surface conductive pattern 3 and the back surface conductive pattern 4 is less than the lower limit, disconnection of the front surface conductive pattern 3 and the back surface conductive pattern 4 may occur. On the other hand, in a case in which the average thickness of the front surface conductive pattern 3 and the back surface conductive pattern 4 exceeds the upper limit, the flexibility of the printed circuit board 1 may decrease unnecessarily.

(First Conductive Pattern)

The front surface first conductive pattern 8 includes a narrow pitch connection portion 15 in which a plurality of terminals are arranged at a constant pitch (center interval). For example, the narrow pitch connection portion 15 is connected to terminals of another device, such as a display panel.

Connection of the terminals to the narrow pitch connection portion 15 can be accomplished, for example, by using surface mounting technology of steps such as solder reflow, thermosetting of a conductive adhesive, and thermal compression bonding using an anisotropic conductive sheet.

The lower limit of the average width of the respective terminals of the narrow pitch connection portion 15 is preferably 3 μm and is more preferably 5 μm. On the other hand, the upper limit of the average width of the respective terminals of the narrow pitch connection portion 15 is preferably 15 μm, and is more preferably 10 μm. In a case in which the average width of the respective terminals of the narrow pitch connection portion 15 is less than the lower limit, the electrical connection of the narrow pitch connection portion 15 to other terminals may be uncertain. Conversely, in a case in which the average width of the respective terminals of the narrow pitch connection portion 15 exceeds the upper limit, devices or circuits such as a display panel with which the flexible printed circuit board 1 can be connected may be limited.

The lower limit of the average interval of the terminals of the narrow pitch connection portion 15 is preferably 3 μm and is more preferably 5 μm. On the other hand, the upper limit of the average interval of the terminals of the narrow pitch connection portion 15 is preferably 15 μm and is more preferably 10 μm. In a case in which the average interval of the terminals of the narrow pitch connection portion 15 is less than the above lower limit, short circuit may occur between the terminals of the narrow pitch connection portion 15. Conversely, in a case in which the average interval of the terminals of the narrow pitch connections 15 exceeds the upper limit, devices with which the flexible printed circuit board 1 can be connected may be limited.

The back surface first conductive pattern 12 includes a wide pitch connection portion 16 in which a plurality of linear or rectangular shaped terminals are arranged at a constant pitch so as to be connected to terminals provided on another printed circuit board or the like.

Similar to the narrow pitch connection portion 15, connection of the terminals to the wide pitch connection portion 16 can be accomplished, for example, by using surface mounting technology of steps such as solder reflow, thermosetting of a conductive adhesive, and thermal compression bonding using an anisotropic conductive sheet.

The lower limit of the average width of the respective terminals of the wide pitch connection portion 16 is preferably 20 μm and is more preferably 25 μm. On the other hand, the upper limit of the average width of the respective terminals of the wide pitch connection portion 16 is preferably 1.0 mm and is more preferably 0.4 mm. In a case in which the average width of the respective terminals of the wide pitch connection portion 16 is less than the lower limit, a circuit that is connected to the wide pitch connection portion 16 may be unnecessarily expensive. Conversely, in a case in which the average width of the respective terminals of the wide pitch connection portion 16 exceeds the upper limit, the flexible printed circuit board 1 or an electronic device using the flexible printed circuit board 1 may become unnecessarily large in size.

The lower limit of the average interval of the terminals of the wide pitch connection portion 16 is preferably 20 μm and is more preferably 25 μm. On the other hand, the upper limit of the average interval of the terminals of the wide pitch connection portion 16 is preferably 1.0 mm and is more preferably 0.4 mm. In a case in which the average interval of the terminals of the wide pitch connection portion 16 is less than the lower limit, short circuit may occur between the terminals of the wide pitch connection portion 16. Conversely, in a case in which the average interval of the terminals of the wide pitch connection portion 16 exceeds the upper limit, the flexible printed circuit board 1 or an electronic device using the flexible printed circuit board 1 may become unnecessarily large in size.

The gold coating layer 7 that is coated on the front surface first conductive pattern 8 and the gold coating layer 11 that is coated on the back surface first conductive pattern 12 protect the front surface first conductive pattern 8 to reduce the electrical resistance of the outer surface. The lower limit of the average thickness of the gold coating layer 7 and the gold coating layer 11 is preferably 0.03 μm and is more preferably 0.09 μm. On the other hand, the upper limit of the average thickness of the gold coating layer 7 and the gold coating layer 11 is preferably 0.9 μm and is more preferably 0.4 μm. In a case in which the average thickness of the gold coating layer 7 and the gold coating layer 11 is less than the lower limit, the front surface first conductive pattern 8 may not be sufficiently protected. Conversely, in a case in which the average thickness of the gold coating layer 7 and the gold coating layer 11 exceeds the upper limit, the flexible printed circuit board 1 may be unnecessarily expensive.

(Second Conductive Pattern)

The second conductive pattern 10 includes lands 17 for IC chip mounting having a planar shape and arrangement corresponding to the terminals of the IC chip 14. By connecting the terminals of the IC chip 14 to the lands 17 for IC chip mounting, the IC chip 14 is connected to the circuit of the flexible printed circuit board 1.

By causing a eutectic reaction with the gold layer on the outer terminal surface of the IC chip 14, the tin coating layer 9 that is coated on the second conductive pattern 10 can easily and reliably mount the IC chip to the lands 17 for IC chip mounting of the second conductive pattern.

The lower limit of the average thickness of the tin coating layer 9 is preferably 0.1 μm and is more preferably 0.2 μm. On the other hand, the upper limit of the average thickness of the tin coating layer 9 is preferably 1.0 μm and is more preferably 0.5 μm. In a case in which the average thickness of the tin coating layer 9 is less than the lower limit, the amount of tin available for a eutectic reaction may be insufficient and the IC chip 14 may not be firmly connected to the lands 17 for IC chip mounting. Conversely, in a case in which the average thickness of the tin coating layer 9 exceeds the upper limit, the tin coating layer 9 may be fluidized at the time of the eutectic reaction to cause a short circuit between circuits of the second conductive pattern 10. It should be noted that the average thickness of the tin coating layer 9 can be measured using, for example, an X-ray fluorescence spectrometer.

As illustrated in FIG. 3 and FIG. 4, on the outer surface of the tin coating layer 9, one or more first areas 18 formed by an alloy of a metal and tin forming the second conductive pattern 10 and one or more second areas 19 formed by unalloyed tin may be formed. In the present embodiment, on the outer surface of the tin coating layer 9, a sea-island structure is formed such that the plurality of first areas 18 are scattered in the second area 19. Also, it is preferable that the plurality of first areas 18 are arranged in the second area 19 at an approximately equal density. The first areas 18 are formed, for example, by alloying tin contained in the tin coating layer 9 with a metal such as copper constituting the second conductive pattern 10 by a heat treatment in the manufacturing process of the flexible printed circuit board 1.

The lower limit of the total occupying area percentage of the one or more first areas 18 in the outer surface of the tin coating layer 9 is preferably 2% and is more preferably 10%. On the other hand, the upper limit of the total occupying area percentage of the one or more first areas 18 in the outer surface of the tin coating layer 9 is preferably 90%, is more preferably 80%, and is further more preferably 70%. In a case in which the total occupying area percentage of the one or more first areas 18 in the outer surface of the tin coating layer 9 is less than the lower limit, the amount of brazing material formed by a eutectic reaction at the time of bonding with terminals of an IC chip increases, and thus a short circuit may occur between adjacent circuits of the second conductive pattern 10. Conversely, in a case in which the total occupying area percentage of the one or more first areas 18 in the outer surface of the tin coating layer 9 exceeds the upper limit, the amount of brazing material formed by a eutectic reaction becomes insufficient, and the bonding with terminals of an IC chip may become insufficient. It should be noted that the total occupying area percentage of the first areas 18 can be measured, for example, by using an energy-dispersive X-ray (EDX) analyzer at a magnification of 5000 times to image the outer surface of the tin coating layer 9 to measure the total occupying area percentage of the plurality of first areas in the outer surface of the tin coating layer 9.

The lower limit of the average thickness of the second area 19 (the average value of thicknesses of all second areas 19 formed on the outer surface of the tin coating layer 9) is preferably 0.05 μm and is more preferably 0.10 μm. On the other hand, the upper limit of the average thickness of the second area 19 is preferably 0.4 μm and is more preferably 0.3 μm. In case in which the average thickness of the second area 19 is less than the lower limit, the amount of brazing material formed by a eutectic reaction becomes insufficient, and the bonding with terminals of an IC chip may become insufficient. On the other hand, in a case in which the average thickness of the second area 19 exceeds the upper limit, the amount of brazing material formed at the time of bonding with terminals of an IC chip increases, and thus a short circuit may occur between circuits of the second conductive pattern 10. It should be noted that the average thickness of the second area 19 can be measured using, for example, an electrolytic film thickness meter.

(Protective Layer)

The front surface protective layer 5 and the back surface protective layer 6 have openings that expose the narrow pitch connection 15, the wide pitch connection portion 16, and the lands 17 for IC chip mounting, and mainly protect portions of the front surface conductive pattern 3 and the back surface conductive pattern 4 that are not covered by the gold coating layers 7 and 11 and the tin coating layer 9.

As the front surface protective layer 5 and the back surface protective layer 6, for example, a coverlay, a solder resist, or the like can be used.

A coverlay used as the front surface protective layer 5 and the back surface protective layer 6 can be configured to include a protective film and an adhesive layer.

The protective film of the coverlay is preferably flexible and insulating. Examples of the main component of the protective film include polyimide, epoxy resin, phenolic resin, acrylic resin, polyester, thermoplastic polyimide, polyethylene terephthalate, fluorine resin, liquid crystal polymer, and the like. In particular, polyimide is preferable in terms of heat resistance. It should be noted that the protective film may contain other resins other than the main component, weather-resistant agents, antistatic agents, and the like.

The lower limit of the average thickness of the protective film is not particularly limited, but is preferably 3 μm and is more preferably 10 μm. Also, the upper limit of the average thickness of the protective film is not particularly limited, but is preferably 500 μm and is more preferably 150 μm. In a case in which the average thickness of the protective film is less than the lower limit, disconnection may easily occur, especially during the manufacturing process. Conversely, in a case in which the average thickness of the protective film exceeds the upper limit, the thickness of the flexible printed circuit board may unnecessarily increase.

An adhesive that constitutes the adhesive layer is not particularly limited, but is preferably one that is excellent in flexibility and heat resistance. Examples of such an adhesive include various resin-based adhesives such as epoxy resins, polyimides, polyesters, phenolic resins, polyurethanes, acrylic resins, melamine resins, and polyamideimides.

The lower limit of the average thickness of the adhesive layer is preferably 5 μm and is more preferably 10 μm. On the other hand, the upper limit of the average thickness of the adhesive layer is preferably 50 μm and is more preferably 40 μm. In a case in which the average thickness of the adhesive layer is less than the lower limit, the adhesion strength of the front surface protective layer 5 and the back surface protective layer 6 may become insufficient. On the other hand, in a case in which the average thickness of the adhesive layer exceeds the upper limit, the flexible printed circuit board may become unnecessarily thick.

As the solder resist that is used for the front surface protective layer 5 and the back surface protective layer 6, a single layer structure such as a photosensitive solder resist or a thermosetting solder resist may be used, or a dry film solder resist including a base film and a resist layer may be used.

Examples of the main component of the solder resist (in the case of the dry film solder resist, the main component of the resist layer) include an epoxy resin, polyimide, and a silicone resin. Among these an epoxy resin, particularly an epoxy acrylate resin, is preferably used. Also, as a base film of the dry film solder resist, for example, polyimide or the like can be used.

The lower limit of the average thickness of the solder resist on the front surface conductive pattern 3 and the back surface conductive pattern 4 is preferably 3 μm and is more preferably 5 μm. On the other hand, the upper limit of the average thickness of the solder resist on the front surface conductive pattern 3 and the back surface conductive pattern 4 is not particularly limited, but is preferably 100 μm and is more preferably 50 μm. In case in which the average thickness of the solder resist on the front surface conductive pattern 3 and the back surface conductive pattern 4 is less than the lower limit, the protection of the front surface conductive pattern 3 and the back surface conductive pattern 4 may become insufficient. Conversely, in a case in which the average thickness of the solder resist on the front surface conductive pattern 3 and the back surface conductive pattern 4 exceeds the upper limit, the flexibility of the printed circuit board may become insufficient.

<IC Chip>

Examples of the IC chip 14 include one that constitutes a part of a circuit at least part of which is formed by the flexible printed circuit board 1, and include one that controls a display panel or the like connected to the narrow pitch connection portion 15.

The IC chip 14 includes terminals at least having an outer surface formed of gold, and these terminals are connected by a eutectic bond to the lands 17 for IC chip mounting of the second conductive pattern 10.

### Advantages

As described above, because the front surface first conductive pattern 8 is coated with the gold coating layer 7 and the back surface first conductive pattern 12 is coated with the gold coating layer 11, the flexible printed circuit board 1 can be easily and securely electrically connected to another device or circuit by ensuring the electrical conductivity of the outer surfaces of the front surface first conductive pattern 8 and the back surface first conductive pattern 12.

Also, in the flexible printed circuit board 1, because the second conductive pattern 10 is coated with the tin coating layer 9, the terminals of the IC chip 14 can be easily and securely mounted by a eutectic reaction.

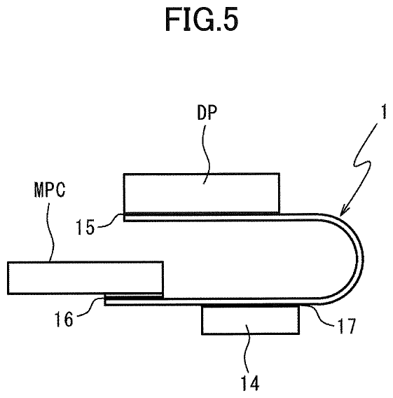

Therefore, as illustrated in FIG. 5, in the flexible printed circuit board 1, in a state in which an IC for driving a display panel is mounted as the IC chip 14 on the lands 17 for IC chip mounting of the second conductive pattern 10, the narrow pitch connection portion 15 of the front surface first conductive pattern 8 can be easily, reliably, and directly connected to terminals of a display panel DP as another device and, the wide pitch connection portion 16 of the back surface first conductive pattern 12 can be easily, reliably, and directly connected to terminals of a main printed circuit board MPC on which the main circuit of an electronic device is formed.

Also, in the flexible printed circuit board 1, the IC chip 14 is mounted in advance on the lands 17 for IC chip mounting of the second conductive pattern 10. For example, for the tin coating layer 9 of the second conductive pattern 10, when heat is applied at the time of connection of terminals of another circuit or the like to the narrow pitch connection portion 15 or the wide pitch connection portion 16, tin may be alloyed with copper that forms the second conductive pattern 10 and the connectivity may decrease. However, by mounting the IC chip 14 on the lands 17 for IC chip mounting in advance, a connection failure of the IC chip 14 can be prevented.

[Method of Manufacturing Flexible Printed Circuit Board]

The flexible printed circuit board 1 of FIG. 1 can be manufactured by a method of manufacturing a flexible printed circuit board according to one embodiment of the present disclosure.

The method of manufacturing a flexible printed circuit board includes: a step of forming a conductive pattern (the front surface conductive pattern 3 and the back surface conductive pattern 4) on the insulating base film 2 (conductive pattern formation step); a step of coating portions of the front surface conductive pattern 3 and the back surface conductive pattern 4 with gold by electroless plating (gold electroless plating step); after the gold electroless plating step, a step of coating different portions of the front surface conductive pattern 3 and the back surface conductive pattern 4 with tin by electroless plating (tin electroless plating step); after the tin electroless plating step, a step of layering the front surface protective layer 5 and the back surface protective layer 6 on portions of the front surface conductive pattern 3 and the back surface conductive pattern 4 that are not covered with gold or tin (protective layer layering step); and a step of eutectic bonding the terminals of the IC chip 14 to the front surface conductive pattern 3 coated with tin (eutectic bonding step).

(Conduction Pattern Formation Step)

In the conductive pattern formation step, the front surface conductive pattern 3 and the back surface conductive pattern 4 are formed on the front and back of the base film 1 by a known method such as a subtractive method or a semi-additive method, for example.

In a typical subtractive method, a metal layer is layered on the front and back surfaces of the base film 2 by, for example, adhesion of a metal foil, deposition of a metal, sintering of metal fine particles, metal plating, or the like, and a resist pattern is formed over a portion corresponding to a front surface conductive pattern 3 and a desired back surface conductive pattern 4 of the metal layer and etched to form the front surface conductive pattern 3 and the back surface conductive pattern 4. Also, in a semi-additive method, a thin seed layer is formed on the front and back surfaces of the base film 2 by, for example, vapor deposition of a metal, sintering of fine metal particles, electroless metal plating, or the like, a resist pattern opening at a portion corresponding to a desired front surface conductive pattern 3 and a desired back surface conductive pattern 4 is formed on the surface of the seed layer, and the front surface conductive pattern 3 and the back surface conductive pattern 4 are formed by electroplating the seed layer exposed in the opening of the resist pattern.

(Gold Electroless Plating Step)

The gold electroless plating step can include a step of forming a resist pattern covering portions other than the portions to be coated with the gold coating layers 7 and 11 of the front surface conductive pattern 3 and the back surface conductive pattern 4, a step of immersing an intermediate product of the flexible printed circuit board on which the resist pattern is formed in an electroless gold plating solution, and a step of peeling off the resist pattern.

(Tin Electroless Plating Step)

The tin electroless plating step can include a step of forming a resist pattern covering a portion other than a portion to be coated with the ting coating layer 9 of the front surface conductive pattern 3 and the back surface conductive pattern 4, a step of immersing an intermediate product of the flexible printed circuit board 1 on which the resist pattern is formed in an electroless tin plating solution, and a step of peeling off the resist pattern. Also, the tin electroless plating step can include a step of heat-treating the intermediate product of the flexible printed circuit board 1 for suppressing generation of whiskers in the tin coating layer 9.

The heat treatment temperature of the heat treatment step can be, for example, greater than or equal to 100° C. and less than or equal to 140° C. Also, the heat treatment time of the heat treatment step can be, for example, greater than or equal to one hour and less than or equal to three hours. It should be noted that in case in which a heat treatment is performed under the above described heat treatment conditions, the average thickness of one or more second areas 19 from the outer surface of the tin coating layer 9 is decreased in a range of approximately 0.1 μm or more and 0.4 μm or less. Therefore, in the step of immersing in the electroless tin plating solution, the immersion time is adjusted so as to form the tin plating layer 9 having a thickness in consideration of the decreased amount in advance.

(Protective Layer Layering Step)

The protective layer layering step uses a known method to layer, for example, a coverlay, solder resist, or the like.

(Eutectic Bonding Step)

In the eutectic bonding step, the terminals of the IC chip 14 are connected by eutectic bonding to the lands 17 for IC chip mounting of the second conductive pattern 10. This eutectic bonding can be accomplished by thermal compression bonding.

The lower limit of the temperature of the thermal compression bonding is preferably 250° C. and is more preferably 270° C. On the other hand, the upper limit of the temperature of the thermal compression bonding is preferably 500° C. and is more preferably and 470° C. In a case in which the temperature of the thermal compression bonding is less than the lower limit, the bonding strength of the terminals of the IC chip 14 to the lands 17 for IC chip mounting may be insufficient. Conversely, in a case in which the temperature of the thermal compression bonding the upper limit, the flexible printed circuit board 1 may be deteriorated by heat.

The lower limit of the pressure of the thermal compression bonding is preferably 2 MPaG and is more preferably 5 MPaG. On the other hand, the upper limit of the pressure of the thermal compression bonding is preferably 50 MPaG and is more preferably 30 MPaG. In a case in which the pressure of the thermal compression bonding is less than the lower limit, the bonding strength of the terminals of the IC chip 14 to the lands 17 for IC chip mounting may be insufficient. Conversely, in a case in which the pressure of the thermal compression bonding exceeds the upper limit, the flexible printed circuit board 1 may deteriorate.

The lower limit of the time of the thermal compression bonding is preferably 0.2 seconds and is more preferably 0.4 seconds. On the other hand, the upper limit of the time of the thermal compression bonding is preferably 20 seconds and is more preferably 10 seconds. In a case in which the time of the thermal compression bonding is less than the lower limit, the bonding strength of the terminals of the IC chip 14 to the lands 17 for IC chip mounting may be insufficient. Conversely, in a case in which the time of the thermal compression bonding exceeds the upper limit, the production efficiency of the flexible printed circuit board 1 may decrease or the flexible printed circuit board 1 may be deteriorated by heat.

According to the method of manufacturing the flexible printed circuit board 1, as described above, it is possible to manufacture the flexible printed circuit board 1 that can be easily, reliably, and electrically connected to another circuit or IC chip.

### Second Embodiment

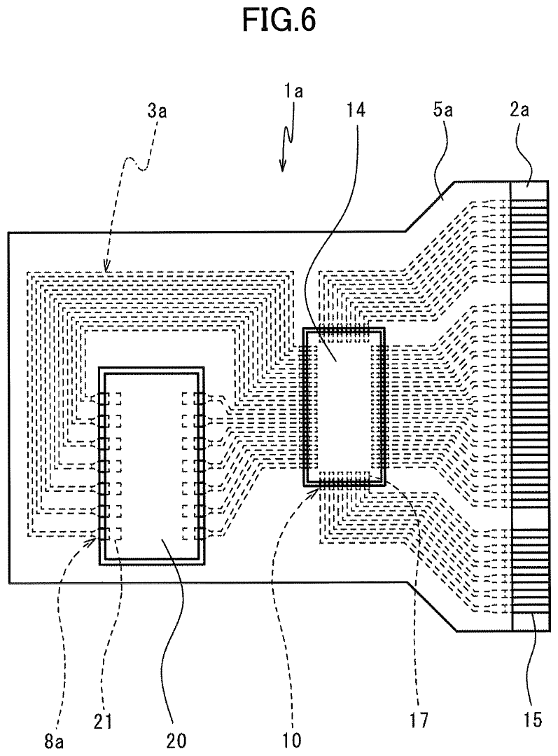

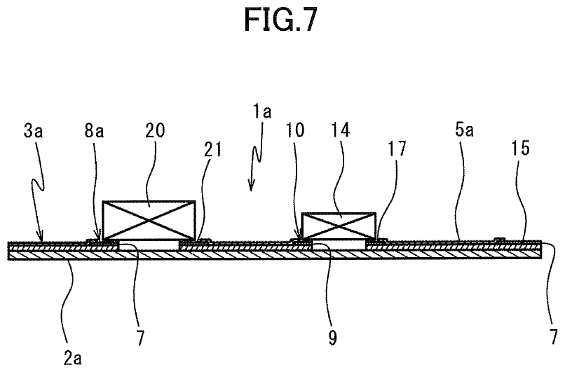

FIG. 6 and FIG. 7 illustrate a flexible printed circuit board 1a according to an embodiment different from that of FIG. 1 of the present disclosure. The flexible printed circuit board 1a further includes an insulating base film 2a, a front surface conductive pattern 3a that is layered on the front surface side of the base film 2a, and a front surface protective layer 5a that partially covers the front surface conductive pattern 3a.

The configuration of the base film 2a, the front surface conductive pattern 3a, and the front surface protective layer 5a in the flexible printed circuit board 1a of FIG. 6 can be similar to the configuration of the base film 2, the front surface conductive pattern 3, and the front surface protective layer 5 in the flexible printed circuit board 1 of FIG. 1, except that the planar shapes are different. Therefore, with respect to the flexible printed circuit board 1a in FIG. 6, the same constituents as those in the flexible printed circuit board 1 in FIG. 1 are referred to by the same numerals and repetitive descriptions are omitted.

The front surface conductive pattern 3a includes a front surface first conductive pattern 8a that is coated by a gold coating layer 7 and includes a second conductive pattern 10 that is coated by a tin coating layer 9.

The front surface first conductive pattern 8a and the second conductive pattern 10 are present at portions that are exposed from the front surface protective layer 5a. In other words, at the front surface conductive pattern 3a, the gold coating layer 7 or the tin coating layer 9 is layered at the portion that is exposed from the front surface protective layer 5a. On the other hand, at the portion that is coated with the front surface protective layer 5a of the front surface conductive pattern 3a, the gold coating layer 7 and the tin coating layer 9 may not be layered.

Also, the flexible printed circuit board 1a includes the IC chip 14 and an electronic component 20 that are mounted on the front surface conductive pattern 3a.

(First Conductive Pattern)

The front surface first conductive pattern 8a includes the narrow pitch connection portion 15 in which a plurality of terminals are arranged at a constant pitch and lands 21 for electronic component mounting having a planar shape and arrangement corresponding to the terminals of the electronic component 20.

For example, the narrow pitch connection portion 15 is connected to terminals of other devices, such as a display panel. Also, the flexible printed circuit board 1a constitutes a main circuit that controls another device such as a display panel that is connected to the narrow pitch connection portion 15 by connecting the terminals of the electronic component 20 to the lands for electronic component mounting.

(Second Conductive Pattern)

The second conductive pattern 10 includes lands 17 for IC chip mounting having a planar shape and arrangement corresponding to the terminals of the IC chip 14. By connecting the terminals of the IC chip 14 to the lands 17 for IC chip mounting, the IC chip 14 is connected to the circuit of the flexible printed circuit board 1a.

### Other Embodiments

The embodiments disclosed above should be considered exemplary in all respects and not limiting. The scope of the present invention is not limited to configurations of the above described embodiments, but is indicated by claims and is intended to include all changes within the meaning and scope of equivalence with the claims.

In the flexible printed circuit board, the first conductive pattern may be coated with nickel or an anti-rust material (coated with a nickel coating layer or an anti-rust coating layer) instead of gold.

It should be noted that the anti-rust coating layer can be formed by applying a commercially available anti-rust material.

In the flexible printed circuit board, the second conductive pattern may be coated with solder (coated with a solder coating layer) instead of tin.

In the flexible printed circuit board, a second conductive pattern may be formed on both sides of the base film. Also, the second conductive pattern may include a wide pitch connection portion. In this case, the IC chip is connected to the second conductive pattern by solder.

The flexible printed circuit board may be a one-sided circuit board without a second conductive pattern, or may be a multi-layered circuit board including a plurality of base films and an additional conductive pattern that is layered between the base films.

On the flexible printed circuit board, an IC chip may not be mounted on the lands for IC chip mounting.

For the flexible printed circuit board, a surface protective layer and a back surface protective layer are not essential.

In the method of manufacturing a flexible printed circuit board, a gold coating layer (or a nickel coating layer) and a tin coating layer (or a solder coating layer) may be formed by electrolytic plating (electroplating) or other methods.

### DESCRIPTION OF THE REFERENCE NUMERALS

1, 1a: flexible printed circuit board
2, 2a: base film
3, 3a: front surface conductive pattern
4: back surface conductive pattern
5, 5a: front surface protective layer
6: back surface protective Layer
7: gold Coating Layer
8: front surface first conductive pattern
8a: first conductive pattern
9: tin coating layer
10: second conductive pattern
11: gold coating layer
12: back surface first conductive pattern
13: through hole
14: IC chip
15: narrow pitch connection portion
16: wide pitch connection portion
17: lands for IC chip mounting
18: first area
19: second area
20: electronic component
21: lands for electric component mounting
DP: display panel
MPC: main printed circuit board

1. A flexible printed circuit board comprising:
an insulating base film;
a first conductive pattern that is layered on the base film and that is coated with gold, nickel, or an anti-rust material; and
a second conductive pattern that is layered on the base film and that is coated with tin or solder.

2. The flexible printed circuit board of claim 1, wherein the second conductive pattern includes lands for IC chip mounting.

3. The flexible printed circuit board according to claim 1, wherein the first conductive pattern includes a narrow pitch connection portion where a plurality of terminals are arranged and formed with an average width of 15 μm or less and at an average interval of 15 μm or less.

4. The flexible printed circuit board according to claim 1, wherein the first conductive pattern includes a wide pitch connection portion where a plurality of terminals are arranged and formed with an average width of 20 μm or more and at an average interval of 20 μm or more.

5. The flexible printed circuit board according to claim 1,
wherein the second conductive pattern is coated with tin,
wherein a layer coated with tin includes, on its outer surface, one or more first areas formed by an alloy of a metal and tin forming the second conductive pattern and one or more second areas formed by unalloyed tin, and
wherein a total occupying area percentage of the one or more first areas in the outer surface of the layer coated with tin is greater than or equal to 2% and less than or equal to 90%.

6. The flexible printed circuit board according to claim 5, wherein an average thickness of the second areas is greater than or equal to 0.05 μm and less than or equal to 0.4 μm.

7. A method of manufacturing a flexible printed circuit board comprising:
forming a conductive pattern on an insulating base film;
coating a portion of the conductive pattern with gold, nickel, or an anti-rust material; and
after the coating, coating another portion of the conductive pattern with tin or solder.

8. The method of manufacturing a flexible printed circuit board according to claim 7,
wherein coating with the gold or nickel is performed by electroless plating, and
wherein coating with the tin or solder is performed by electroless plating.

9. The method of manufacturing a flexible printed circuit board according to claim 7,
wherein the portion of the conductive pattern that is coated with tin or solder includes lands for IC chip mounting, and
wherein the method further includes eutectic bonding terminals of an IC chip to the lands for IC chip mounting.

10. The method of manufacturing a flexible printed circuit board according to claim 9, wherein in the eutectic bonding, by thermal compression bonding at a temperature of 250° C. or more and 500° C. or less and at a pressure of 2 MPaG or more and 50 MPaG or less, eutectic bonding is performed.
